(19) United States
(12) Patent Application Publication
(10) Pub. No.: US 2026/0095040 A1
(43) Pub. Date: Apr. 2, 2026

(54) SEMICONDUCTOR DEVICE WITH ACROSS-THE-BARRIER ESD PROTECTION

(71) Applicant: Texas Instruments Incorporated, Dallas, TX (US)

(72) Inventors: Himanth Mudda, Kakinada (IN); Krishna Praveen Mysore Rajagopal, Manteca, CA (US); Shubham Panjrath, Bangalore (IN); Kumar Anurag Shrivastava, Bangalore (IN); Prathamesh Shanbhag, Dharwad (IN); Rahul Prakash, Bangalore (IN)

(21) Appl. No.: 19/194,252

(22) Filed: Apr. 30, 2025

Related U.S. Application Data
(60) Provisional application No. 63/700,020, filed on Sep. 27, 2024.

(51) Int. Cl. H02H 9/00; H02H 9/02; H10D 89/60

(52) U.S. Cl. CPC H02H 9/005; H02H 9/02; H10D 89/814

(57) ABSTRACT

A semiconductor device including across-the-barrier (ATB) ESD protection circuitry configured to handle IEC currents. In one example, the semiconductor device comprises a circuit including a first port and a second port, a first clamp disposed between the first and second ports and configured to be coupled between two terminals of a coil of an isolation transformer, and a second clamp disposed between the first clamp and a reference node of the circuit.

### CROSS-REFERENCE TO RELATED APPLICATIONS

This application claims the benefit of and priority to U.S. Provisional Application No.: 63/700,020, filed on Sep. 27, 2024, which is hereby fully incorporated herein by reference.

### FIELD OF THE DISCLOSURE

Disclosed implementations relate generally to the field of semiconductor devices and fabrication. More particularly, but not exclusively, the disclosed implementations relate to semiconductor devices including an isolation barrier.

### BACKGROUND

Galvanic isolation is a principle of isolating functional sections of electrical systems or integrated circuits (ICs) to prevent current flow while energy or information can still be exchanged between the sections by other means, such as induction or electromagnetic waves, capacitance, or by optical, acoustic or mechanical means. Galvanic isolation is typically used where two or more electric circuits communicate but their grounds or reference nodes may be at different potentials. It is an effective method of breaking ground loops by preventing unwanted current from flowing between two units sharing a reference conductor. Galvanic isolation is also used for safety, preventing accidental current flows from reaching ground though a person's body.

Isolators are devices designed to minimize direct current (DC) and unwanted alternating current (AC) transient currents between two systems or circuits by using suitable isolation barriers, while allowing data and power transmission between the two. In some applications, isolators also act as a barrier against high voltage in addition to allowing the system to function properly.

As advances in the design of integrated circuits and semiconductor fabrication continue to take place, improvements in microelectronic devices including isolation barriers are also being concomitantly pursued.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device including across-the-barrier (ATB) electrostatic discharge (ESD) protection circuitry is disclosed. In one arrangement, the semiconductor device comprises a circuit including a first port and a second port, a first clamp disposed between the first and second ports and configured to be coupled between two terminals of a coil of an isolation transformer; and a second clamp disposed between the first clamp and a reference node of the circuit. In one arrangement, the first clamp may comprise a pair of grounded-gate n-channel MOS (GGNMOS) transistors having respective sources coupled to a shared node, where each GGNMOS transistor has a corresponding drain coupled to a respective one of the first and second ports. In one arrangement, the second clamp may comprise a GGNMOS transistor, which may be larger than the GGNMOS transistors of the first clamp. In one arrangement, a source of the GGNMOS transistor of the second clamp is coupled to the shared node and a drain thereof is coupled to a reference node of the circuit.

In one example, an isolator is disclosed, which comprises a first circuit including a first pair of ports and a second circuit including a second pair of ports, where the first and second pairs of ports may be configured to support a communication channel between the first and second circuits. The isolator comprises an isolation transformer disposed between the first and second circuits, where a first coil of the isolation transformer is coupled to the first pair of ports and a second coil of the isolation transformer is coupled to the second pair of ports. The isolator comprises a first distributed clamp coupled to the first pair of ports; a first lumped clamp disposed between the first distributed clamp and a first reference node of the first circuit; a second distributed clamp coupled to the second pair of ports; and a second lumped clamp disposed between the second distributed clamp and a second reference node of the second circuit. In one arrangement, the distributed clamps of the isolator may each comprise a pair of GGNMOS transistors similar to the first clamp in the above example. In one arrangement, the lumped clamps of the isolator may each comprise a GGNMOS transistor similar to the second clamp in the example above.

In one example, an electronic circuit is disclosed, which comprises a first circuit portion configured to energize first and second interface nodes in a differential mode with a data signal; and a second circuit portion configured to energize the first and second interface nodes in a common mode in response to an electrostatic discharge.

In one example, a system is disclosed, which comprises: a processing unit; a signal isolator coupled to the processing unit; and an interface coupled to the isolator, the isolator including an isolation barrier between a first circuit and a second circuit. In one arrangement, the first circuit is operable to communicate with the processing unit and the second circuit is operable to communicate with the interface, where the first and second circuits may each include a hierarchical ESD protection circuit operable to route ESD current that crosses the isolation barrier to a respective reference node of the first or second circuits.

In one example, a semiconductor device is disclosed, which comprises a first MOS transistor formed over a semiconductor substrate and having a first gate, first source region and a first drain region; a well extending into the semiconductor substrate; second and third MOS transistors formed in or over the well, the second MOS transistor having a second gate, a second source region and a second drain region, and the third MOS transistor having a third gate, a third source region and a third drain region; and a shared node that connects the well, the first gate, first source region, second source region, second gate, third source region and third gate.

In one example, a method of fabricating a semiconductor device including an isolation barrier is disclosed. The method may comprise: forming a first distributed clamp and a first lumped clamp in a first circuit, the first distributed clamp coupled to a first pair of ports of the first circuit associated with a communication channel, the first lumped clamp disposed between the first distributed clamp and a first reference node of the first circuit; forming a second distributed clamp and a second lumped clamp in a second circuit, the second distributed clamp coupled to a second pair of ports of the second circuit associated with the communication channel, the second lumped clamp disposed between the second distributed clamp and a second reference node of the second circuit; and coupling an isolation transformer to the first and second circuits, where a first coil of the isolation transformer is connected to the first pair of ports of the first circuit and a second coil of the isolation transformer is connected to the second pair of ports of the second circuit.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIGS. 1A-1C illustrate microelectronic devices including across-the-barrier (ATB) electrostatic discharge (ESD) protection (AEP) circuitry operable with a transformer-based isolation barrier according to some examples of the present disclosure;

FIG. 2A illustrates a microelectronic device including AEP circuit portions with additional details according to some examples;

FIGS. 2B and 2C depict circuit schematics corresponding to the microelectronic device of FIG. 2A under different ESD scenarios;

FIG. 3 is a cross-sectional view of a semiconductor device or a portion thereof illustrating isolation tank structures for forming a distributed clamp and a lumped clamp as part of AEP circuitry according to some examples;

FIGS. 4A and 4B together depict an end-to-end system including a 4-channel isolator having a hierarchical AEP architecture according to some examples;

FIG. 5 depicts a packaged device including an isolator according to some examples; and

FIG. 6 is a flowchart according to an example method of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. Whereas these terms may sometimes be used in a similar manner depending on the context, they are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples will be set forth below in the context of isolation barrier implementations including transformers.

Circuit isolation, also known as galvanic isolation, prevents direct current (DC) and unwanted alternating current (AC) signals from passing from one functional block of a system or a circuit to another functional block or circuit that needs to be protected, as previously noted. Among its uses, isolation maintains signal integrity of the system or circuit by preventing high-frequency noise from propagating, protects sensitive circuitry from voltage/current spikes (e.g., during electrostatic discharge (ESD) or surge events), and provides safety for human operators.

High voltages present in certain application environments such as factory automation, motor drives, grid infrastructure and hybrid/electric vehicles (H/EVs), etc., can be several hundred or even thousands of volts. Galvanic isolation helps resolve the challenge of designing a safe human interface in the presence of such high voltages.

In some example arrangements, isolation may be achieved by implementing one or more isolation transformers as part of an isolation barrier between two circuits, where the transformers may be configured to provide physical and electrical separation between the two circuits. In operation, the isolation transformer may exchange electrical energy from a primary coil to a secondary coil using magnetic, or inductive, coupling, while isolating and protecting sensitive electronic circuitry from discharge events.

Isolation transformers may be deployed in a variety of applications including, e.g., digital isolators used to isolate digital signals and transfer digital communication across an isolation barrier. In some arrangements, digital isolators comprising isolation transformers may be implemented in multi-channel communication systems configured to carry digitized data streams where isolation between different digital input/output (I/O) blocks may be desired. In some arrangements, digital I/O blocks may comprise multi-channel I/O circuits based on complementary metal oxide semiconductor (CMOS) technology, low voltage CMOS (LVCMOS) technology, etc.

Isolation transformers may comprise a pair of coils separated by a dielectric material having a suitable thickness depending on the intended isolation barrier implementation. In some arrangements, center tap (CT) transformers may be used as isolation transformers in isolators. In such examples, a center tap connection may form an electrical contact made to or at a point in a coil winding (or inductor) of the transformer. Center tap contacts may provide grounded paths for dissipating current spikes that may be encountered by circuits having isolation barriers in certain system-level ESD events, which may fall within a range of testing conditions set forth in applicable International Electrotechnical Commission (IEC) standards. For example, IEC 61000-4-2 standard, incorporated by reference herein, sets forth compliance requirements for maintaining isolation barrier integrity under certain testing conditions that are more stringent than chip-level ESD standards such as human body model (HBM), machine model (MM) and charged device Model (CDM). Although chip-level ESD protection circuitry may help mitigate current spikes falling within the IEC 61000-4-2 standard, referred to herein as “IEC currents”, the chip-level ESD protection circuitry may not completely dissipate the IEC currents in some arrangements.

In some ESD scenarios it is therefore possible that IEC currents may be triggered that could damage the internal circuitry of a circuit as well as propagate across the isolation barrier between two circuits, thus potentially compromising the barrier integrity. For example, depending on the waveform characteristics and/or frequency of the occurrence of IEC current spikes, the propagation of such spikes across an isolation barrier may cause dielectric breakdown and/or render the dielectric material susceptible to reduced lifetime during test and/or in the field (e.g., time-dependent dielectric breakdown or TDDB). Whereas a grounded CT connection arrangement in the transformers may facilitate protection against IEC currents in such scenarios, additional connections and/or pinouts necessary for center tapping may increase the area of an isolation transformer, however. In some arrangements, increased area requirements of CT transformers may lead to extra cost as well as reduced number of transformer dies per wafer, especially in multi-channel applications requiring an isolation barrier across several communication channels.

In some arrangements, non-center-tap (nCT) transformers requiring fewer connections may be used for achieving isolation in some applications, e.g., low-cost applications. As the number of connections may be minimized, standalone nCT transformers may require less die area, thus potentially leading to cost and area savings. However, lack of grounding paths via center tap connections may increase the risk of IEC current vulnerability in such arrangements because a substantial amount of current may remain coupled to the communication channels, which may increase the isolation barrier's susceptibility to dielectric failure as noted above.

Examples of the present disclosure recognize the foregoing challenges and provide a transformer-based isolation solution where protection against IEC currents may be provided even in nCT transformer implementations. An across-the-barrier (ATB) ESD protection (AEP) architecture according to some examples may comprise a hierarchical arrangement of distributed clamps and lumped clamps provided symmetrically in each side of an isolation barrier. In some examples, an IEC current may be divided into smaller IEC current segments that may be safely propagated in common mode across the barrier with minimal risk to the dielectric material. In some arrangements, an example AEP architecture may be configured to provide appropriate levels of ATB ESD protection in compliance with applicable standards and specifications (e.g., IEC 61000-4-2) while benefiting from cost and area savings of an nCT transformer implementation. Whereas the examples of the present disclosure may provide various AEP architectures as well as associated structures, materials and processes that may engender these and other beneficial effects, no particular result is a requirement unless explicitly recited in a particular claim.

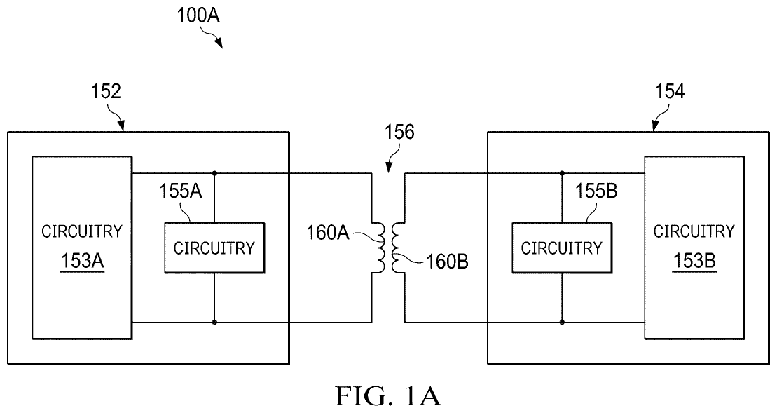

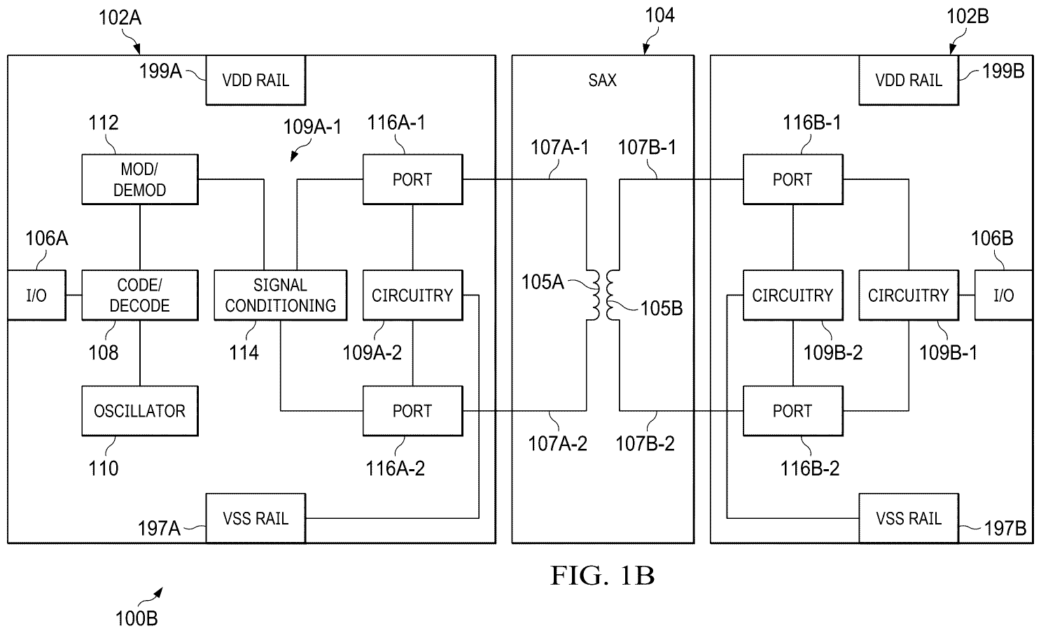

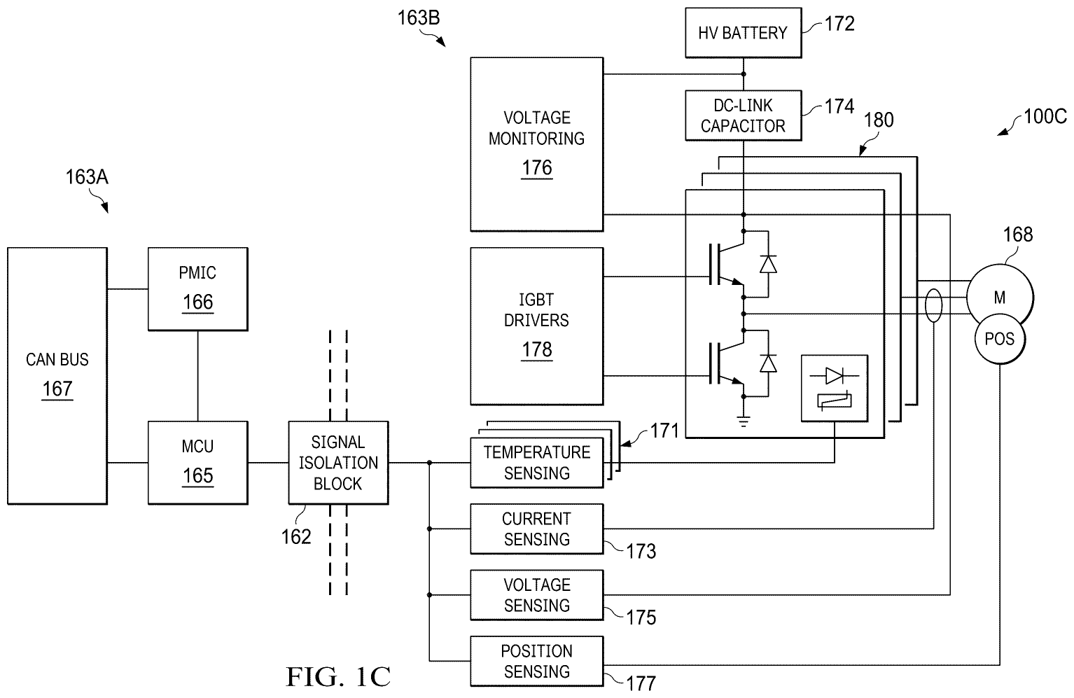

Turning to the drawings, FIG. 1A depicts a schematic diagram of a microelectronic device 100A that may include an isolation barrier between two circuits 152 and 154, where across-the-barrier (ATB) ESD protection (AEP) circuitry may be provided according to some examples. In some versions, a microelectronic device such as the microelectronic device 100A may also be referred to as a semiconductor device, an electronic circuit, etc. Without limitation, the microelectronic device 100A may be configured to operate in digital, analog, and/or mixed-signal application environments where isolation between two circuits or circuit portions, e.g., circuits 152 and 154, is desired. In some arrangements, isolation barrier functionality may be effectuated by one or more isolation transformers, e.g., isolation transformer(s) 156, coupled between the circuits 152 and 154. In some arrangements, the isolation transformers 156 may be provided based on the number of communication channels disposed between the circuits 152 and 154. In some arrangements, each communication channel between the circuits 152 and 154 may be configured to operate with a respective isolation transformer 156.

For purposes of the present disclosure, an isolation transformer may also be referred to as a “transformer” or an “isolator” in some examples. In some arrangements, the isolation transformers 156 may be configured to operate at high voltages, e.g., 500 V or greater, in order to provide high voltage isolation between the circuits 152 and 154. By way of illustration, the microelectronic device 100A may be deployed in digital communication systems, servo motor control, factory automation, power supplies, solar or wind power generation, computer peripheral interfaces, data acquisition, data center (DC) infrastructure, robotic control, autonomous vehicular control including unmanned aerial and/or automotive vehicle control, etc., to name a few example application scenarios. In some examples, the circuits 152, 154 may each comprise circuitry 153A, 153B, respectively, for effectuating communications therebetween using differential signaling based on inductive coupling of coils, e.g., coils 160A, 160B, of respective isolation transformers 156. Furthermore, the circuits 152, 154 may each comprise circuitry 155A, 155B, respectively, for effectuating AEP functionality using common mode transmission of IEC currents across the isolation barrier from a first circuit (e.g., circuit 152) encountering an ESD event to a second circuit (e.g., circuit 154), or vice versa, based on parasitic capacitive coupling between the coils 160A, 160B of the isolation transformers 156.

In some arrangements, circuit 152 includes circuitry or circuit portion 153A that may be coupled to first coils 160A of the corresponding transformers 156 on a channel-by-channel basis. Likewise, circuit 154 includes circuitry or circuit portion 153B couped to respective second coils 160B of the corresponding transformers 156, where the first and second coils 160A, 160B of an isolation transformer 156 are inductively/magnetically coupled for effectuating communications and/or power transfer between the circuits 152 and 154. In operation, transformers 156 allow the circuits 152, 154 to communicate with each other without a conductive connection, e.g., a wired connection, between the two circuits 152, 154 while using modulated signals across the isolation barrier on a channel-by-channel basis.

Each circuit 152, 154 may further include respective circuitry or circuit portion 155A, 155B for effectuating AEP functionality as noted above. In some examples, circuit portions 155A and 155B may be referred to as AEP circuit portions, AEP circuits or AEP circuitry, etc., which may be provided as part of a hierarchical protection architecture that may be configured to divide an ESD surge current, e.g., IEC current, into multiple current segments and propagate the current segments across the isolation barrier in common mode using capacitive coupling between the coils. In some examples, IEC current segments from one circuit, e.g., circuit 152, may be propagated across multiple isolation transformers 156 to the other circuit, e.g., circuit 154, while maintaining isolation barrier integrity in a manner that complies with applicable IEC standards. In some examples, IEC current segments may be propagated across the isolation barrier such that the barrier integrity is or remains in compliance with the IEC 61000-4-2 standard, incorporated by reference hereinabove, that defines various levels of ESD protection based on contact discharge and air gap discharge testing methodologies. As will be set forth below, the hierarchical protection architecture of the circuit portions 155A/155B may include a plurality of distributed clamps connected to a common lumped clamp provided for the circuits 152 and 154, respectively, where each distributed clamp may be operable with a corresponding communication channel and the lumped clamp may be connected to a node having a grounded path connection.

FIG. 1B depicts a microelectronic device 100B including an isolation transformer 104 as an isolation barrier disposed between two circuits 102A, 102B having AEP functionality according to an example. In some arrangements, the microelectronic device 100B is a variation or representative example of the microelectronic device 100A described above, where the circuits 102A and 102B are roughly analogous to the circuits 152 and 154 of FIG. 1A with additional details shown therein.

In some implementations, the microelectronic device 100B is illustrative of a semiconductor device, e.g., an integrated circuit, where circuits 102A and 102B may be provided as circuit portions operable in two voltage domains, respectively, that may require isolation therebetween. In such implementations, the isolation transformer 104 may be monolithically integrated within the integrated circuit (e.g., on a same semiconductor substrate). In some implementations, the microelectronic device 100B is illustrative of a multi-chip device, e.g., where the circuits 102A and 102B may be formed on separate substrates (e.g., chips or dies) having circuitry operating in different voltage domains. In some multi-chip implementations, the isolation transformer 104 may comprise a standalone transformer (SAX) on a separate substrate or may be integrated with one of the circuits, e.g., circuit 102A or 102B. Regardless of whether the isolation transformer 104 is integrated with either circuits 102A, 102B or provided as a standalone isolation device, the isolation transformer 104 may include a first coil 105A and a second coil 105B, either of which may be designated as a primary (or first) coil or a secondary (or second) coil depending on application. Further, analogous to the coils 160A, 160B of the transformer 156 shown in FIG. 1A, the coils 105A, 105B may be operable at different voltages.

Without limitation, the microelectronic device 100B is illustrated as an isolator for effectuating communication between the circuits 102A and 102B disposed in a bidirectional communication system including two endpoints (not specifically shown in FIG. 1B). In one arrangement, circuit 102A may be interfaced with a first endpoint or subsystem via input/output (I/O) circuitry 106A configured to support one or more communication channels. In similar fashion, circuit 102B may be interfaced with a second endpoint or subsystem via I/O circuitry 106B configured to support a corresponding number of communication channels. Depending on the direction of communications, circuits 102A and 102B may be operable as a transmitter (Tx), a receiver (Rx), or both, e.g., on a channel-by-channel basis.

In some arrangements, communications between the circuits 102A and 102B may be effectuated using differential signaling where a communication signal on a channel is provided as a pair of differential signals across a corresponding isolation transformer 104. Differential signaling may be used in some applications for improving the performance and quality of signal transmission, e.g., with better immunity to noise. Accordingly, the microelectronic device 100B may include a plurality of isolation transformers 104 depending on the number of communication channels between the circuits 102A and 102B. With respect to each communication channel supported by the circuits 102A, 102B, a pair of ports, interface nodes or internal I/O terminals may therefore be provided in each circuit 102A, 102B for coupling with a respective coil side of a corresponding isolation transformer 104. For example, one coil of an isolation transformer 104 may be coupled between a pair of ports or interface nodes of one circuit and the other coil of the isolation transformer 104 may be coupled between a corresponding pair of ports or interface nodes of the other circuit with respect to a corresponding communication channel of a plurality of communication channels. As illustrated, ports 116A-1 and 116A-2 of the circuit 102A are coupled to terminals 107A-1 and 107A-2 of the coil 105A of the isolation transformer 104 with respect to a communication channel. Likewise, corresponding ports 116B-1 and 116B-2 of the circuit 102B are coupled to terminals 107B-1 and 107B-2 of the coil 105B of the isolation transformer 104.

In operation, a communication signal received in one circuit, e.g., circuit 102A, on a channel for transmission to the other circuit, e.g., circuit 102B, may be coded, modulated, and conditioned as differential signals (e.g., a pair of inverted and non-inverted signals) that may be received by the other circuit across the corresponding isolation transformer 104. The other circuit 102B may include circuitry for demodulating and decoding the received signals to construct the communication signal for subsequent downstream transmission. Because the microelectronic device 100B may be configured as a bidirectional digital isolator in an example implementation, both circuits 102A, 102B may include circuitry for coding/decoding, modulation/demodulation, signal conditioning, oscillator circuitry, etc. Whereas a coding/decoding circuit 108, oscillator 110, modulation/demodulation circuit 112 and a signal conditioning circuit 114 are specifically shown as part of overall circuitry 109A-1 of the circuit 102A, analogous circuits may also be provided as part of overall circuitry 109B-1 of the circuit 102B in some example arrangements. Further, each circuit 102A, 102B may be provided with respective supply voltage (VDD) rails 199A, 199B and reference voltage (VSS or ground) rails 197A, 197B. Depending on application, circuits 102A and 102B may employ a variety of modulation schemes, e.g., on-off keying (OOK), phase shift keying (PSK), frequency shift keying (FSK), etc., for effectuating communications between the endpoints of the overall system.

For purposes of some examples, circuitry 109A-1 of the circuit 102A may be configured as a circuit portion operable to energize ports 116A-1 and 116A-2 (as well as additional port pairs in a multi-channel implementation) in a differential mode with data signals for effectuating communications with the circuit 102B on a channel-by-channel basis. In similar fashion, circuitry 109B-1 of the circuit 102B may be configured as a circuit portion operable to energize ports 116B-1 and 116B-2 as well as additional port pairs with suitable data signals for effectuating communications with the circuit 102A in differential mode.

Further, circuits 102A, 102B may comprise circuit portions 109A-2, 109B-2, respectively, where the circuit portions 109A-2, 109B-2 may be coupled to respective pairs of ports 116A-1/116A-2, 116B-1/116B-2 (as well as additional port pairs in a multi-channel implementation) for effectuating AEP functionality. Similar to the circuit portions 155A, 155B mentioned above with respect to the example of FIG. 1A, the circuit portions 109A-2 and 109B-2 may comprise a hierarchical protection architecture operable to propagate IEC current segments across the isolation barrier in response to system-level ESD events. In some arrangements, circuit portion 109A-2 of the circuit 102A may be configured to energize ports 116A-1 and 116A-2 as well as additional port pairs in a common mode in response to an ESD event encountered at an I/O terminal of the circuit 102A so as to safely propagate a surge current to the circuit portion 109B-2. In similar fashion, circuit portion 109B-2 of the circuit 102B may be configured to energize ports 116B-1 and 116B-2 as well as additional port pairs in a common mode in response to an electrostatic discharge event encountered at an I/O terminal of the circuit 102B in order to safely propagate the IEC surge current to the circuit portion 109A-2.

In some arrangements, circuit portions 109A-1 and 109A-2 of the circuit 102A may be referred to as first and second circuit portions, respectively, in reference to the circuit 102A. Likewise, circuit portions 109B-1 and 109B-2 of the circuit 102B may also be referred to as first and second circuit portions, respectively, in reference to the circuit 102B.

FIG. 1C depicts a traction inverter system 100C that may include an isolation barrier block 162 comprising a plurality of transformers disposed between circuitry including AEP architecture according to some examples. In some arrangements, the traction inverter system 100C may be deployed in a hybrid electric vehicle (HEV) or a full electric vehicle (EV) for converting a DC supply from the vehicle's HV battery, e.g., battery 172, into AC output that powers an electric motor 168 of the vehicle. As illustrated, the traction inverter system 100C may include various blocks or modules that may be disposed or operable in respective low voltage (LV) or high voltage (HV) domains, e.g., LV domain 163A and HV domain 163B, which may be separated by the isolation barrier block 162. In some HEV/EV implementations, an LV domain may refer to voltages less than 60V-100V and an HV domain may refer to voltages over 100V. In some arrangements, the isolation barrier block 162 may include a plurality of isolation transformers (not specifically shown in FIG. 1C) depending on the type and number of blocks/modules and associated communication channels requiring isolation.

In one arrangement, the traction inverter system 100C may include a power management IC (PMIC) module 166 and a microcontroller unit (MCU) 165 operable in the LV domain 163A that communicate via a controller area network (CAN) bus 167. HV domain modules may include the battery 172 (e.g., a Li-ion battery bank), a DC link capacitor 174, a plurality of sensing blocks such as temperature sensing block 171, current sensing block 173, voltage sensing block 175, and position sensing block 177, as well as various protection and monitoring blocks 176 and power transistors 180 configured to control the motor 168. In some examples, the power transistors 180 may comprise insulated-gate bipolar transistors (IGBT), SiC FETs or Group III-V devices including GaN devices. The power transistors 180 are operable to control the flow of current to the motor 168 to generate motion, and may be monitored and protected by sensing the temperature, voltage and current of the power transistors 180 during operation. Further, the power transistors 180 may be controlled by MCU 165 via gate drivers 178 that may also include suitable isolation barriers (not shown in FIG. 1C) for facilitating high side operation and low side operation of the traction inverter system 100C. Accordingly, at least a portion of the traction inverter system 100C may include a circuit arrangement similar to the arrangement shown in FIG. 1A, where a circuit or module operable in the LV domain 163A and another circuit or module operable in the HV domain 163B are isolated by and coupled via the isolation barrier block 162.

During operation of the motor 168, voltage, current and position signals are sensed and fed back to MCU 165 to modify a modulation scheme (e.g., pulse-width modulation or PWM) used by the traction inverter system 100C to supply power. In some examples, feedback signals may be processed by MCU 165 for providing a field-oriented control (FOC) mechanism that utilizes mathematical transformations to generate proper control signals for driving the power transistors at suitable frequencies in order to control power output. As accurately sensed signals transmitted between LV and HV domains are important in providing efficient motor control, it is desirable that the integrity of the isolation barrier of the traction inverter system 100C is not degraded due to the propagation of IEC currents across the barrier.

Additional details regarding an example implementation of the traction inverter system 100C may be found in Texas Instruments Application Note SLUA963B, “HEV/EV Traction Inverter Design Guide—Using Isolated IGBT and SiC Gate Drivers,” Revised October 2022, which is incorporated in its entirety by reference herein.

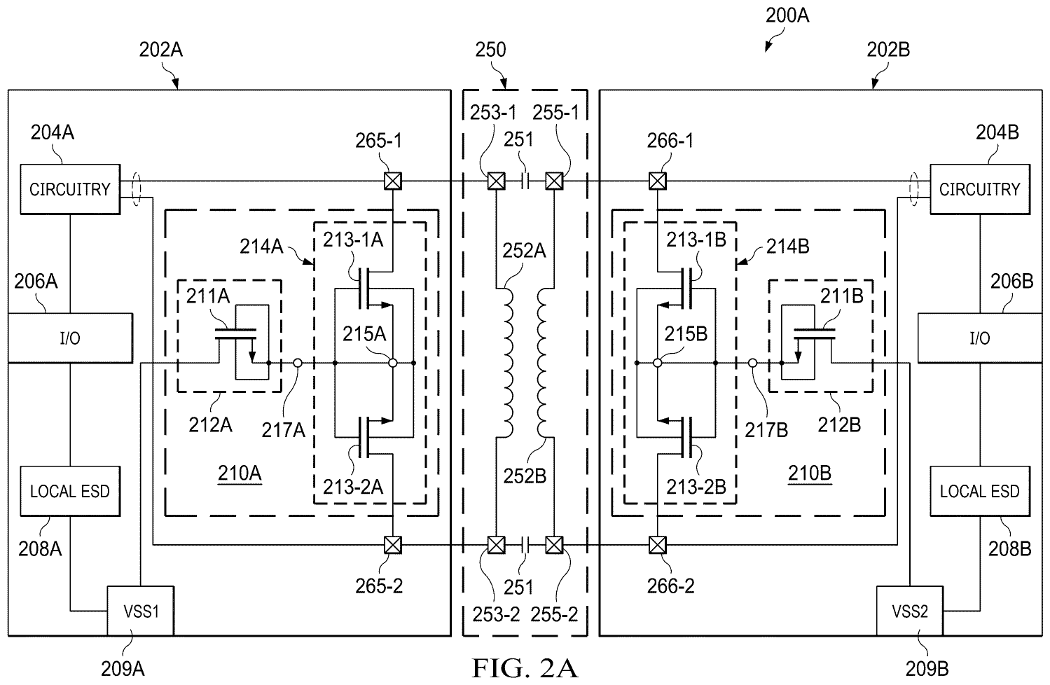

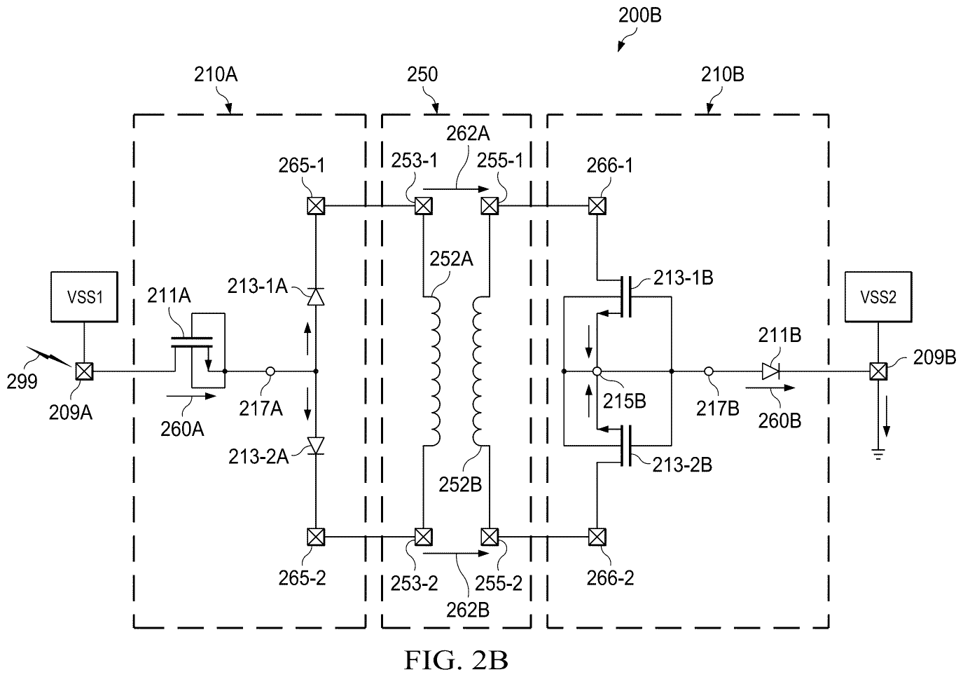

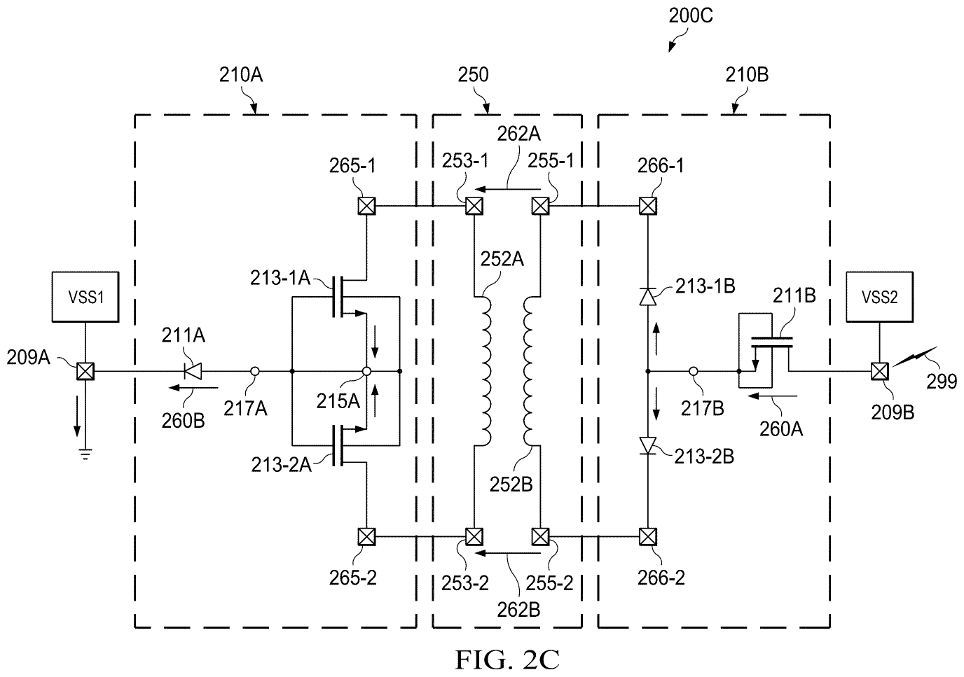

FIG. 2A depicts a microelectronic device 200A including an isolation transformer 250 as an isolation barrier disposed between two circuits 202A, 202B, where each circuit 202A, 202B may include a respective AEP circuit portion 210A, 210B according to some examples. In some respects, the microelectronic device 200A is a variation or representative example of the microelectronic devices 100A, 100B described above. Accordingly, the circuits 202A and 202B of the microelectronic device 200A are roughly analogous to the circuits 102A, 102B of FIG. 1B and/or circuits 152, 154 of FIG. 1A, with additional details shown therein with respect to effectuating AEP functionality according to an implementation. Furthermore, the microelectronic device 200A may be implemented in an application environment such as the traction inverter system 100C set forth above, e.g., as part of the isolation barrier block 162. In some arrangements, therefore, AEP circuit portions 210A, 210B of circuits 202A, 202B, respectively, may be provided as representative implementations of circuit portions 155A, 155B of FIG. 1A and/or circuit portions 109A-2, 109B-2 of FIG. 1B.

Similar to some examples described above, the microelectronic device 200A is operable to support multiple communication channels between the circuits 202A and 202B using differential signaling. Accordingly, circuitry 204A and circuitry 204B of circuits 202A and 202B, respectively, are operable to energize multiple pairs of ports or interface nodes in differential mode, where data signals may be received from and/or transmitted to upstream and downstream endpoints (not shown in FIG. 2A) via respective I/O terminals 206A, 206B. In an example arrangement including N communication channels, there may be 2N ports for effectuating differential mode signaling between the circuits 202A and 202B. Further, respective AEP circuit portions 210A, 210B may each include a plurality of distributed clamps coupled to corresponding pairs of ports, where each plurality of distributed clamps may be coupled to a common lumped clamp in a hierarchical ATB ESD architecture provided as part the respective AEP circuit portion 210A/210B. Whereas AEP circuit portions 210A, 210B may include N distributed clamps in an N-channel configuration, a single-channel distributed clamp arrangement is illustrated in FIG. 2A for the sake of simplicity in order to provide a general description of AEP functionality as an example without limitation.

In some arrangements, circuits 202A and 202B may include local ESD protection circuitry 208A, 208B, e.g., operable to protect respective core circuit portions, e.g., circuitry 204, 204B, respectively, against certain types of chip-level ESD events, e.g., events consistent with models such as the human body model (HBM), the charge device model (CDM), and the machine model (MM). However, there may be ESD events that may exhibit transient waveforms having faster rise times and/or current/voltage characteristics beyond the requirements of HBM/CDM/MM models that may not be adequately blocked or safely shunted by the local ESD protection circuitry 208A, 208B as previously noted. In such scenarios, IEC currents generated at a circuit, e.g., circuit 202A, due to an ESD event thereat may potentially damage the core circuitry 204A of the circuit 202A. Further, IEC currents may compromise the integrity of the isolation barrier because the energy propagated to the isolation transformers 250 may be beyond the blocking capability of the dielectric materials used in the fabrication of the isolation transformers 250. Moreover, any IEC currents received across the isolation barrier at a circuit (e.g., circuit 202B) due to parasitic capacitive coupling between the isolation transformer coils, e.g., coils 252A, 252B, may also damage the circuitry 204B therein because the local ESD protection circuitry 208B may not be operable and/or configured to handle such across-the-barrier (ATB) events.

To provide bidirectional protection against ATB IEC currents, some examples herein may include symmetrically configured AEP circuit portions 210A, 210B of circuits 202A, 202B, respectively. As noted above, each AEP circuit portion 210A, 210B may include N distributed clamps for an N-channel implementation, that may be coupled to corresponding pairs of interface nodes or ports. Further, the N distributed clamps may be organized in a hierarchical manner so as to ultimately connect to a lumped clamp configured to shunt ATB IEC currents to a ground rail in a circuit, e.g., circuit 202A or 202B.

In the single-channel example shown in FIG. 2A, a distributed clamp 214A provided as part of AEP circuit portion 210A is coupled between nodes, terminals or ports 265-1, 265-2, which are respectively coupled to coil terminals 253-1 and 253-2 of coil 252A of the isolation transformer 250. A lumped clamp 212A is coupled to the distributed clamp 214A, where the lumped clamp 212A may be coupled to a reference rail or node (VSS1) 209A, which may be provided with a grounded path (not shown in FIG. 2A) for dissipating ESD currents shunted via local ESD protection circuitry 208A as well as ATB IEC currents from the circuit 202B received via AEP circuit portion 210A. Although not explicitly shown in FIG. 2A, the lumped clamp 212A of circuit 202A may also be commonly coupled to other distributed clamps provided with respect to other channels. In some examples, distributed clamp 214A and lumped clamp 212A may be referred to as first and second clamps, respectively, or vice versa.

In similar fashion, AEP circuit portion 210B of the circuit 202B may include a distributed clamp 214B coupled between nodes, terminals or ports 266-1, 266-2, which are respectively coupled to coil terminals 255-1 and 255-2 of coil 252B of the isolation transformer 250. Also, a lumped clamp 212B is coupled to the distributed clamp 214B, where the lumped clamp 212B may be coupled to a reference rail or node (VSS2) 209B of the circuit 202B. Similar to VSS1 209A of the circuit 202A, VSS2 209B may be provided with a grounded path (not shown in FIG. 2B) for dissipating ESD currents shunted via local ESD protection circuitry 208B and/or ATB IEC currents from the circuit 202A received via AEP circuit portion 210B. Further, the lumped clamp 212B of circuit 202B may be commonly coupled to other distributed clamps provided with respect to other channels (not shown in FIG. 2B). Similar to the arrangement of circuit 202A, distributed clamp 214B and lumped clamp 212B of circuit 202B may be referred to as first and second clamps, respectively, or vice versa.

In an example arrangement, the distributed clamps 212A, 212B as well as corresponding lumped clamps 214A, 214B may be implemented using grounded-gate n-channel MOSFET (GGNMOS) devices, sometimes referred to as GGNMOS for brevity, that may be appropriately sized depending on application. The term “grounded-gate” means the gate and source of the MOSFET are shorted together, though need not be actually grounded. As will be set forth below, GGNMOS devices may be advantageously configured to operate in snapback mode or diode mode depending on the direction of the propagation of IEC currents across an isolation barrier such as the isolation transformer 250.

To facilitate transmission of IEC current segments developed from capacitive coupling (illustratively shown as a parasitic capacitance 251) between the coils 252A and 252B associated with a single channel, a distributed clamp associated with the channel may be implemented as a pair of GGNMOS devices that are coupled at a common source node, also referred to as a distributed clamp shared node. Further, a drain of each GGNMOS device in the distributed clamp may be coupled to a respective port of the pair of ports associated with the single channel. Accordingly, in an N-channel implementation where there are N distributed clamps in an AEP circuit portion, each distributed clamp comprising a pair of GGNMOS devices having a shared source, respective drains may be coupled to corresponding ports of the associated port pairs configured for the N channels. Furthermore, the common sources of all distributed clamps for an N-channel implementation may be coupled to a source of a GGNMOS device operable as a lumped clamp having a grounded path connection as previously noted.

In the single channel example shown in FIG. 2A, the distributed clamp 214A of AEP circuit portion 210A may be implemented as a pair of GGNMOS devices 213-1A, 213-2A coupled at a common source node 215A, where the drain of GGNMOS 213-1A is coupled to port 265-1 and the drain of GGNMOS 213-2A is coupled to port 265-2 of the circuit 202A. Likewise, the distributed clamp 214B of AEP circuit portion 210B may be implemented as a pair of GGNMOS devices 213-1B, 213-2B coupled at a common source node 215B, where the drain of GGNMOS 213-1B is coupled to port 266-1 and the drain of GGNMOS 213-2B is coupled to port 266-2 of the circuit 202B.

In an example arrangement, the lumped clamp 212A of AEP circuit portion 210A may be implemented as a GGNMOS device 211A, where a source of GGNMOS 211A is coupled to the common source node 215A of the distributed clamp(s) 214A at a node 217A and a drain of GGNMOS 211A is coupled to a reference node, e.g., VSS1 209A, of the circuit 202A. In similar fashion, the lumped clamp 212B of AEP circuit portion 210B may be implemented as a GGNMOS device 211B, where a source of GGNMOS 211B is commonly coupled to the common source node 215B of the distributed clamp(s) 214B at a node 217B and a drain of GGNMOS 211B is coupled to a reference node, e.g., VSS2 209B, of the circuit 202B.

In the examples herein, the GGNMOS devices used as lumped clamps may be larger than the GGNMOS devices used for implementing distributed clamps depending on the application and technology node. For example, lumped clamp GGNMOS devices may be about at least 5 times larger (e.g., wider) than the GGNMOS devices used for distributed clamps for a given technology node. By being at least 5 times larger the lumped clamp GGNMOS devices may have a drive current capacity that is about 5 times or more than the GGNMOS devices used for distributed clamps. In versions of this example, a lumped clamp GGNMOS device may be ten times larger than the distributed clamp GGNMOS devices.

When an I/O terminal of a circuit encounters an ESD event causing an IEC current, the VSS node of that circuit is energized and the corresponding AEP circuit portion of the circuit (referred to herein as a transmitting AEP circuit portion) is operable to progressively divide the IEC current into multiple IEC current segments (e.g., 2N segments for an N-channel implementation) of lower current values (e.g., having equal magnitudes depending on line impedance characteristics in the AEP circuit portion. The distributed clamps of the AEP circuit portion may be configured to propagate the current segments via capacitive coupling of the isolation barrier to the other circuit via the isolation barrier. The AEP circuit portion of the other circuit (referred to herein as a receiving AEP circuit portion) is operable to receive the current segments via the isolation barrier and combine the current segments into a total IEC current, which may be propagated by the lumped node of the receiving AEP circuit portion to the VSS node of the circuit for shunting to a grounded path.

To facilitate end-to-end propagation of IEC currents in the microelectronic device 200A, the GGNMOS devices in each AEP circuit portion 210A, 210B of the circuits 202A, 202B may be configured operate in a snapback mode or a diode mode depending on the voltages at respective drains and sources of the devices in an ESD scenario as will be set forth below.

In some arrangements, lumped clamps and distributed clamps of an AEP circuit portion may be formed in respective isolation tanks fabricated in a semiconductor substrate to prevent unwanted electrical interactions between adjacent circuitry or other components forming a microelectronic device such as the microelectronic device 200A. In some arrangements, the lumped clamps and distributed clamps of a AEP circuit portion may be formed in a shared isolation tank. In some arrangements, the lumped clamps and distributed clamps may not be disposed in isolation tanks, e.g., where the lumped clamps and distributed clamps may be placed in a semiconductor device with respect to remaining portions of the circuitry such that the risk of unwanted electrical interactions with the circuitry is minimized or eliminated.

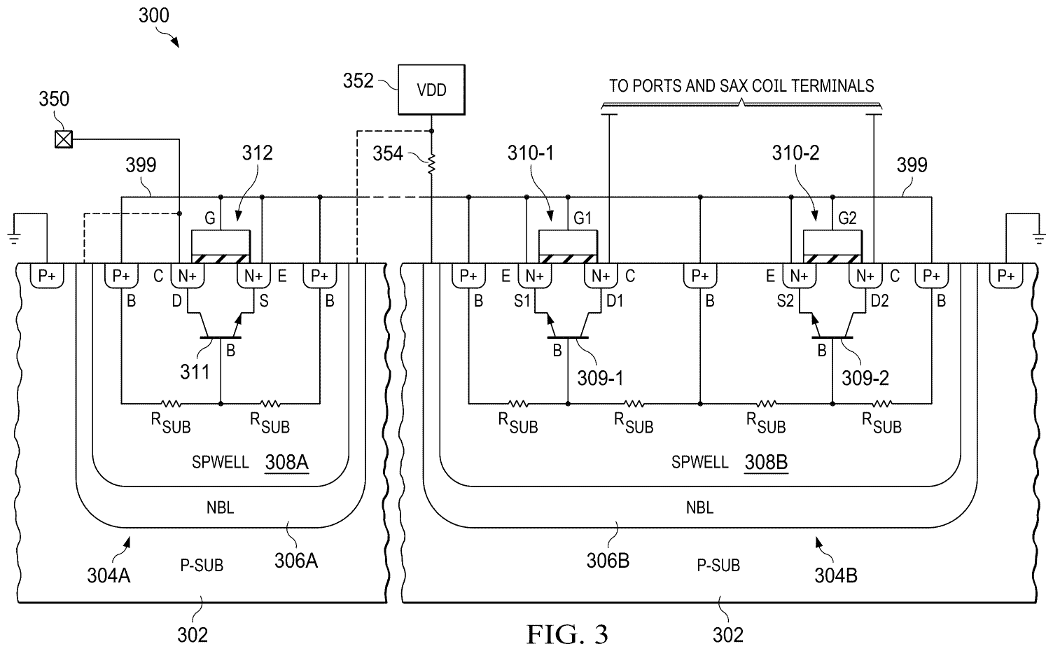

Without limitation, reference is taken to FIG. 3, which depicts a cross-sectional view of a portion of a semiconductor device 300 that illustrates an arrangement of a GGNMOS device 312 formed in an isolation tank 304A and a pair of GGNMOS devices 310-1, 310-2 formed in another isolation tank 304B. In this arrangement, the GGNMOS device 312 is operable as a lumped clamp and the GGNMOS devices 310-1/310-2 are operable as a distributed clamp of an AEP circuit portion corresponding to a single channel. In some examples, the GGNMOS device 312 may be about 5 to 10 times larger than the GGNMOS devices 310-1, 310-2 as previously noted.

In one example, isolation tanks 304A, 304B may be formed in a p-type substrate (P-SUB) 302 such as a lightly doped epitaxial layer, where a deep n-well buried layer (NBL) structure surrounding a shallow p-well (SPWELL) formed therein provides junction isolation with respect to the p-type substrate 302. In versions of this example, SPWELL is operable as a region for forming the GGNMOS devices for purposes of the present disclosure. Depending on implementation, NBL and SPWELL structures of an isolation tank may have suitable net doping densities.

As illustrated in FIG. 3, GGNMOS 312 is formed in SPWELL 308A surrounded by NBL 306A of the isolation tank 304A. In similar manner, GGNMOS 310-1 and GGNMOS 310-2 are formed in SPWELL 308B surrounded by NBL 306B of the isolation tank 304B. In some examples, SPWELLs 308A, 308B may be referred to as first and second wells, respectively, or vice versa. Likewise, isolation tanks 304A, 304B may be referred to as first and second wells, respectively, or vice versa. In the examples herein, the gate, source and body of respective GGNMOS devices are tied together, e.g., as grounded-gate devices, via a shared circuit node. Further, the shared circuit node may be floating, e.g., without a fixed voltage level, until voltages may be developed at the shared circuit node in response to IEC currents in an ESD event. On the other hand, the drains of GGNMOS devices of an AEP circuit portion may be coupled to different nodes in a circuit depending on whether the GGNMOS device is operable as a lumped clamp or as part of a distributed clamp.

In one example arrangement, the drains of GGNMOS 310-1 and GGNMOS 310-2, which operate as distributed clamp devices, may be coupled to corresponding ports or interface nodes of the semiconductor device 300 (not specifically shown in FIG. 3), where the ports may in turn be coupled to isolation transformer coil terminals associated with a channel as described above. Further, the sources of GGNMOS 310-1 and GGNMOS 310-2 are tied together at a shared circuit node 399 to which the gates and bodies of GGNMOS 310-1 and GGNMOS 310-2 are also coupled. Moreover, the shared circuit node 399 is connected to the source, drain and body of the lumped clamp device, e.g., GGNMOS 312. The drain of GGNMOS 312 may be coupled to a node 350, e.g. a protected circuit node. In some examples, node 350 may correspond to VSS1 209A or VSS2 209B shown in the example of FIG. 2A. For purposes herein, shared circuit node 399 may be implemented as one or more conductive traces, e.g. silicide bridges and/or metal-level interconnects.

In some examples, it is desirable that the pn junction between SPWELL 308B and NBL 306B of the isolation tank 304B remains reverse-biased so as to ensure adequate isolation during operation with respect to a range of voltages that may appear at the ports, e.g., negative and/or positive voltage ranges. Accordingly, NBL 306B of the isolation tank 304B may be coupled to a positive rail 352, e.g., VDD, via a pullup resistor 354. In some examples, the pullup resistor 354 may have a resistance about 0.5 MΩ to 1.5 MΩ and VDD may be about 5 V. On the other hand, NBL 306A of the isolation tank 304A may be biased in multiple ways depending on implementation. In some examples, NBL 306A may be coupled to the drain of lumped clamp device GGNMOS 312 shown by an example ghost line. In some examples, NBL 306A may be coupled to VDD 352 via a resistor such as resistor 354 or directly without a resistor, as shown by a second example ghost line. Furthermore, P-SUB 302 of the semiconductor device 300 may be provided with a substrate contact that may be connected to a ground, e.g., chip ground, in some examples.

Because the gate is shorted to the source in a GGNMOS device, the GGNMOS device may not be turned on in normal operation as a MOSFET device. However, a parasitic NPN bipolar junction transistor (BJT) that may be formed in the GGNMOS device may be turned on in a snapback mode when the voltage at the drain operating as a collector of the parasitic NPN BJT device increases beyond a voltage limit. For example, a parasitic NPN BJT 311 may be formed with respect to GGNMOS 312, where the n-type drain is operable as the collector, the n-type source is operable as the emitter and the p-body of SPWELL 308A is operable as the base of the parasitic NPN BJT 311. In similar fashion, parasitic NPN transistors 309-1 and 309-2 may be formed with respect to GGNMOS 310-1 and GGNMOS 310-2, respectively, as shown in FIG. 3.

In snapback mode, e.g., when the voltage at the drain/collector exceeds a limit, the collector-base junction of a parasitic NPN BJT becomes reverse biased to the point of avalanche breakdown, causing a reverse current. As a result, the current flowing from the base to ground induces a voltage potential across a parasitic body resistor, R_{SUB}, causing a positive potential to appear across the base-to-emitter(source) junction. Accordingly, the base-to-emitter(source) junction (e.g., pn junction) becomes forward-biased, thus triggering the parasitic NPN device 311, which causes a current flow from the drain (collector) to the source (emitter) of the GGNMOS device. On the other hand, when a voltage appears at the source/emitter (e.g., in a reverse direction), the parasitic NPN BJT is turned off but the body-to-collector(drain) junction (e.g., pn junction) becomes forward-biased, which causes a current flow to the drain of the GGNMOS device in a diode mode.

Accordingly, depending on whether a current is propagated from a lumped GGNMOS device, e.g., due to an ESD event, towards the isolation barrier, or whether a current is propagated across the isolation barrier (e.g., due to capacitive coupling) to the lumped GGNMOS device, the GGNMOS devices of a microelectronic device may be configured to operate in different modes, e.g., snapback mode or diode mode, as set forth above. In some examples, an end-to-end AEP architecture of a microelectronic device may therefore include AEP circuit portions with lumped and distributed clamp GGNMOS devices operating in different modes depending on the direction of IEC current flow that in turn may depend on which side of the isolation barrier an ESD event may have been triggered.

By way of example, referring back to FIG. 2A and taking reference to FIGS. 2B and 2C in conjunction therewith, circuit schematics 200B and 200C corresponding to an end-to-end AEP architecture of the microelectronic device 200A of FIG. 2A are illustrated in FIGS. 2B and 2C under different ESD scenarios, respectively. In the example of FIG. 2B, an ESD event occurs at an I/O terminal of the circuit 202A that is transmitted to VSS1 209A as ESD surge 299. As the drain of GGNMOS 211A of the AEP circuit portion 210A is coupled to VSS1 209A, GGNMOS 211A is operable to conduct an IEC current 260A in snapback mode using a parasitic NPN BJT structure as set forth above. The IEC current 260A may be divided, e.g., into two IEC current segments having similar or same magnitudes, at the common source node 215A of the distributed clamp 214A. Because of the voltage developed at the sources of GGNMOS 213-1A and GGNMOS 213-2A, each GGNMOS 213-1A, 213-2A is operable in diode mode to propagate a respective IEC current segment to the corresponding port 265-1, 265-2 of circuit 202A coupled thereto. As described previously, ports 265-1 and 265-2 are coupled to coil terminals 253-1 and 253-2, respectively, of coil 252A of the isolation transformer 250. Because of the capacitive coupling between coils 252A and 252B, the IEC current segments may be propagated across the isolation barrier as IEC current segments 262A, 262B, that may energize coil terminals 255-1 and 255-2 respectively, of coil 252B of the isolation transformer 250, which in turn are coupled to ports 266-1 and 266-2 of the circuit 202B.

With respect to the AEP circuit portion 210B, the drains of GGNMOS 213-1B and GGNMOS 213-2B of the distributed clamp 214B are coupled to corresponding ports 266-1, 266-2, respectively, of the circuit 202B. Because of the voltages developed at the respective drains of GGNMOS 213-1B and GGNMOS 213-2B, each GGNMOS 213-1B, 213-2B is operable in snapback mode based on a respective parasitic NPN BJT structure as set forth above. Accordingly, GGNMOS 213-1B and GGNMOS 213-2B are operable to propagate the IEC current segments to the common source node 215B, where the IEC current segments may be combined into a total IEC current 260B. In versions of this example, the total IEC current 260B is expected to be nearly identical to or the same as the IEC current 260A generated at VSS1 209A due to the ESD event.

Because the source of GGNMOS 211B operating as the lumped clamp of the AEP circuit portion 210B is coupled to the common source node 215B, the parasitic NPN BJT structure of GGNMOS 211B is turned off. GGNMOS 211B is therefore operable in diode mode to propagate the IEC current 260B to a reference node, e.g., VSS2 209B, coupled to the drain of GGNMOS 211B. As noted previously, VSS2 209B may be provided with a ground path connection for safely discharging the received IEC current. In this manner, an IEC current triggered at an I/O terminal of the circuit 202A may be propagated across the isolation barrier to a node of the circuit 202B configured to operate as part of a discharge path for the received system-level IEC current.

Circuit schematic 200C of FIG. 2C illustrates IEC current propagation in a direction (e.g., a second direction or reverse direction) opposite to the IEC current propagation direction (e.g., a first direction or forward direction) as set forth above. In the example of FIG. 2C, an ESD event occurs at an I/O terminal of the circuit 202B that may be propagated to VSS2 209B as ESD surge 299. Except that the operational modes of the GGNMOS devices of the end-to-end AEP circuit architecture of the circuit 200C are swapped in the reverse direction of propagation, i.e., snapback mode GGNMOS devices are changed to diode mode GGNMOS devices, and vice versa, the functionality of the end-to-end AEP circuit architecture is essentially a symmetrical counterpart of the functionality of the end-to-end AEP circuit architecture of the circuit 200B. Accordingly, only certain salient features will be set forth below with respect to the circuit 200C without limitation.

Because the drain of the lumped clamp GGNMOS device 211B is coupled to VSS2 209B, GGNMOS 211B is operable in snapback mode to propagate an IEC current 260A to the distributed clamp GGNMOS devices 213-1B, 213-2B, which receive the IEC current 260A at the common source node 215B. Accordingly, the distributed clamp GGNMOS devices 213-1B, 213-2B of the AEP circuit portion 210B are operable in diode mode to divide the IEC current 260A and propagate the resulting IEC current segments to respective ports and corresponding coil terminals 255-1, 255-2. The IEC current segments are propagated across the isolation barrier due to capacitive coupling between the coils 252A and 252B as before. Accordingly, IEC current segments 262A, 262B are received at respective drains of the distributed clamp GGNMOS devices 213-1A, 213-2B of the AEP circuit portion 210A, which now operate in snapback mode. The common source node 215A associated with the distributed clamp GGNMOS devices 213-1A, 213-2A is operable to combine the IEC current segments and propagate the total IEC current 260B to the source of the lumped clamp GGNMOS device 211A.

As the source of GGNMOS 211A operating as the lumped clamp of the AEP circuit portion 210A is coupled to the common source node 215A, the parasitic NPN BJT structure of GGNMOS 211A is turned off. GGNMOS 211A is therefore operable in diode mode to propagate the total IEC current 260B to a reference node, e.g., VSS1 209A, coupled to the drain of GGNMOS 211A. Because VSS1 209A may be provided with a ground path connection for dissipating the received IEC current, the total IEC current 260B may be safely discharged in the circuit 202A.

Whereas FIGS. 2A-2C illustrate a single-channel end-to-end AEP architecture in particular detail, similar some examples may include multi-channel arrangements, e.g., including N channels between circuits 202A and 202B, as previously noted. In such arrangements, an example end-to-end AEP circuit architecture may include N distributed clamps in the respective AEP circuit portions 210A, 210B, where each AEP circuit portion may include a single lumped clamp having its source coupled to a node, e.g., node 217A or 217B, that may be coupled to the common source nodes (e.g., nodes 215A or nodes 215B) of the N distributed clamps. Accordingly, a lumped clamp in such multi-channel AEP architectures may be referred to as a shared clamp in some examples herein. In a forward direction of propagation, the shared/lumped clamp may be configured to divide an IEC current into N IEC current segments, each of which may in turn be subdivided into two segments by respective distributed clamps for propagation across the isolation barrier. In a reverse direction of propagation, the commonly coupled source node of the shared/lumped clamp may be configured to combine N IEC current segments received from respective distributed clamps into a total IEC current for propagation to a reference node having a ground path connection.

In general operation, a multi-channel AEP architecture may therefore be configured to divide a total injected IEC current ultimately into 2N current segments of smaller value (IEC_{Segment}=IEC_{Total}/2N), which may be more amenable to propagation across an isolation barrier with minimal risk to the dielectric material of the barrier. In some arrangements, injected IEC currents may range from about 8 A to 15 A, and may have rise times in the range of a few hundred picoseconds. In baseline implementations including nCT isolation transformers, such IEC current spikes are expected to be detrimental to the circuitry as well as the dielectric material of the nCT isolation transformers. However, the hierarchical nature of an end-to-end AEP architecture of the present disclosure allows dividing injected IEC currents even with sharp rise times into smaller segments that can be safely handled by the nCT isolation transformers. Accordingly, the examples herein may facilitate robust isolation implementation in a variety of applications while utilizing more economical nCT isolation transformers.

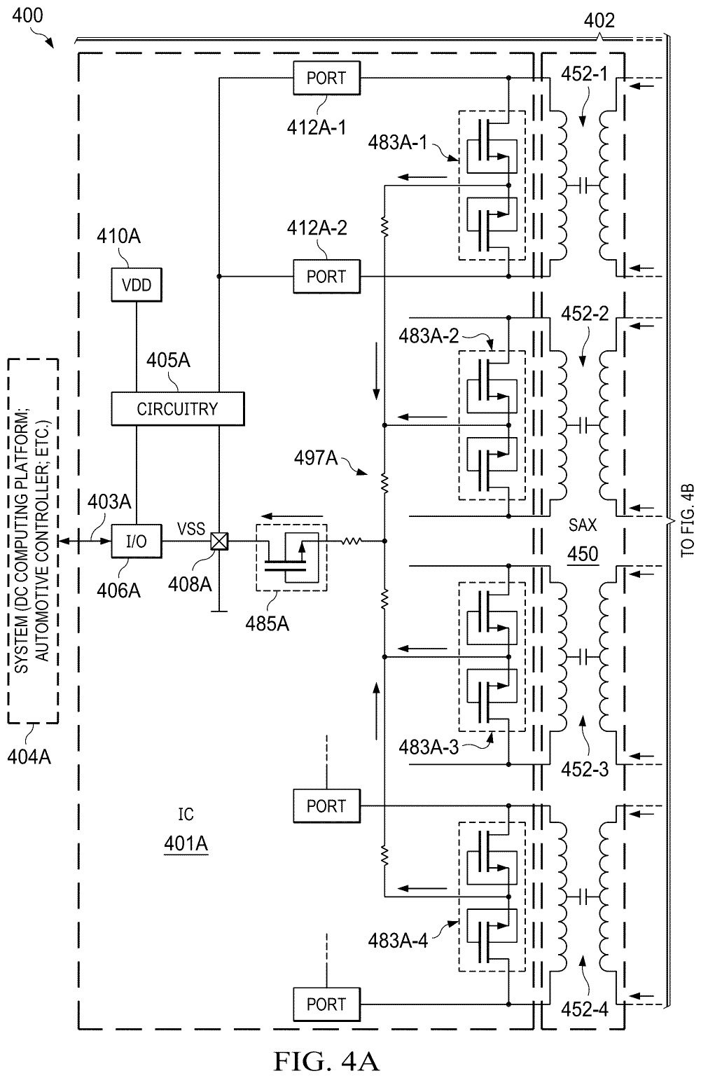

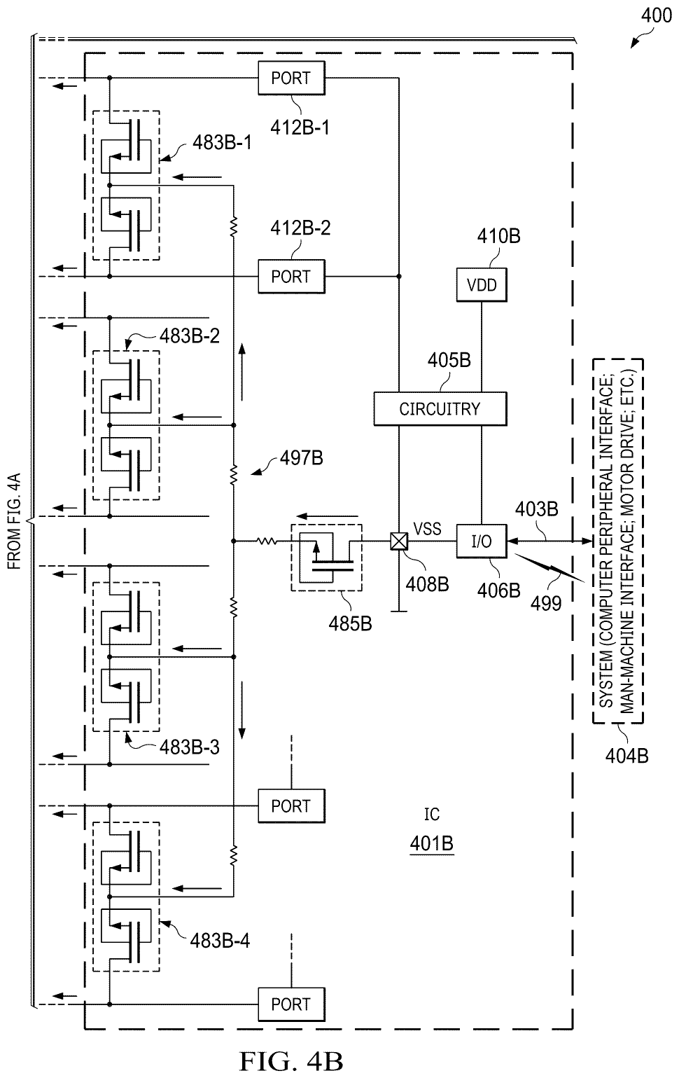

FIGS. 4A and 4B together depict an end-to-end system 400 including a 4-channel isolator 402 disposed between endpoints 404A and 404B that may be operable in different voltage domains. Depending on implementation of the system 400, endpoints 404A may be representative of data center (DC) nodes or platforms, automotive controllers, traction inverters, etc. and endpoints 404B may be representative of computer peripheral interfaces, man-machine interfaces, motor drive interfaces, etc. The isolator 402 may include a circuit 401A, a circuit 401B and a SAX 450 disposed therebetween, roughly analogous to the examples of FIGS. 1A-1C and 2A described above. Accordingly, similar to the foregoing examples, circuits 401A, 401B and SAX 450 may be provided as one or more IC dies or chips depending on the level of integration, which may be packaged in a multichip module (MCM) package in some examples.

Endpoints 404A and 404B may communicate with circuits 401A and 401B using a plurality of communication paths 403A, 403B, respectively, for transmitting and receiving signals with respect to effectuating communications between endpoints 404A and 404B. Circuits 401A, 401B may therefore comprise suitable I/O circuitry 406A, 406B as well as communications circuitry 405A, 405B, respectively. Each circuit 401A, 401B may have corresponding VDD and VSS nodes, e.g., VDD 410A and VSS 408A with respect to circuit 401A and VDD 410B and VSS 408B with respect to circuit 401B. Further, circuit 401A and circuit 401B may each include a plurality of ports or interface nodes configured to facilitate multi-channel communications between circuits 401A and 401B via SAX 450. Although circuits 401A, 401B may each include local ESD protection circuitry coupled to corresponding I/O circuitry 406A, 406B, respectively, such local ESD protection circuitry is not shown for the sake of simplicity.

SAX 450 may comprise four isolation transformers 452-1 to 452-4 to provide isolation with respect to four communication channels between the circuits 401A and 401B, where differential signaling may be used for communications. Accordingly, circuits 401A, 401B may each include four pairs of ports, each pair for facilitating differential signaling with respect to a corresponding channel. By way of illustration, ports 412A-1, 412A-2 are associated with circuit 401A corresponding to a single channel and ports 412B-1, 412B-2 are associated with circuit 401B corresponding to that channel. Further, isolation transformer 452-1 is disposed between port pair 412A-1/412A-2 and port pair 412B-1/412B-2 such that terminals of a first coil of the isolation transformer are couped to the port pair 412A-1/412A-2 in circuit 401A and terminals of a second coil of the isolation transformer are coupled to the 412B-1/412B-2 in circuit 401B. In similar manner, coil terminals of remaining three isolation transformers 452-2 to 452-4 are coupled to respective port pairs disposed in each circuit 401A, 401B on per-channel basis.

To facilitate AEP functionality across the SAX barrier, circuits 401A and 401B may each include a corresponding AEP circuit portion 497A, 497B that may comprise four distributed clamps coupled to a lumped clamp in a hierarchical manner as previously described. Accordingly, each distributed clamp may be disposed between the ports of a port pair of a circuit on per-channel basis, where the drains of the GGNMOS devices forming the distributed clamp may be coupled to the respective ports. By way of illustration, the drains of the GGNMOS devices forming distributed clamp 483A-1 of the AEP circuit portion 497A are coupled to ports 412A-1, 412A-2 in circuit 401A. Likewise, the drains of the GGNMOS devices forming distributed clamp 483B-1 of the AEP circuit portion 497B are coupled to ports 412B-1, 412B-2 in circuit 401B. In similar manner, the drains of distributed clamps 483A-2 to 483A-4 and the drains of distributed clamps 483B-2 to 483B-4 may be coupled to corresponding port pairs of the respective circuits 401A, 401B.

Each AEP circuit portion 497A, 497B further comprises a corresponding lumped clamp 485A, 485B, respectively, that is commonly coupled to common source nodes of the distributed clamps. To ensure that equal or nearly equal IEC current segments are generated, uniform transmission characteristics, e.g., matching resistance, inductance and capacitance, may be maintained between the lumped clamp and associated distributed clamps in some examples. In one arrangement, isolation tanks or cells containing the lumped clamps and isolation tanks or cells containing respective distributed clamps may be suitably placed in a circuit layout corresponding to the circuits 401A, 401B. Further, conductive traces connecting the lumped and distributed clamps may be appropriately routed in respective circuits 401A, 401B according to some example implementations.

As described previously, the lumped clamps 485A, 4985B of AEP circuit portions 497A, 497B, may each be implemented as a GGNMOS device that may be suitably sized relative to the sizes of GGNMOS devices of the corresponding distributed clamps, e.g., distributed clamps 483A-1 to 483A-4 and distributed clamps 483B-1 to 483B-4. The drains of the GGNMOS devices forming the lumped clamps 485A, 485B may be coupled to respective reference nodes, e.g., VSS 408A and 408B.

In an example ESD scenario 499 involving a terminal of I/O circuitry 406B, an IEC current may be propagated by the lumped clamp 485B operating in snapback mode, which may be divided into four IEC current segments initially that may be propagated to respective distributed clamps 484B-1 to 483B-4. Each of the distributed clamps 484B-1 to 483B-4 is operable to subdivide a respective IEC current segment into two IEC current segments. Accordingly, a total of 8 IEC current segments may be ultimately generated and propagated by the distributed clamps 484B-1 to 483B-4 in diode mode similar to the example of FIG. 2C. Due to capacitive coupling between the coils of the isolation transformers 452-1 to 452-4, the IEC current segments may be propagated across SAX barrier to the distributed clamps 483A-1 to 483A-4 of the AEP circuit portion 497A of circuit 401A, where each distributed clamp is operable to combine two IEC current segments. As described previously, the distributed clamps 483A-1 to 483A-4 are operable in snapback mode similar to the example of FIG. 2C. Accordingly, the distributed clamps 483A-1 to 483A-4 each propagate a sum of two IEC current segments to respective common source nodes, which are coupled to the source of GGNMOS device forming the lumped clamp 485A via a shared node. The shared node coupled to the source of the lumped clamp 485A combines all four IEC current segments as a total IEC current. In this condition, the GGNMOS device of the lumped clamp 485A is operable in diode mode, thus allowing the propagation of the total IEC current to VSS 408A to which the drain of the GGNMOS device of the lumped clamp 485A is coupled. As previously set forth, VSS 408A may be provided with a ground path connection for dissipating the IEC current in a safe manner.

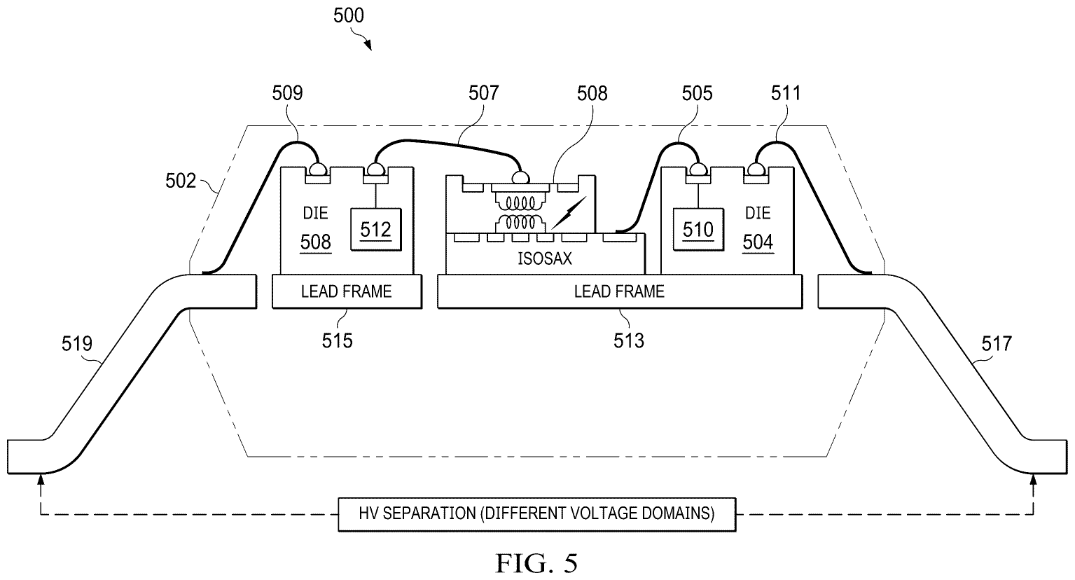

FIG. 5 depicts a packaged device 500 including a SAX chip 506 coupled between a first die 504 and a second die 508, where each die may include a respective AEP circuit portion 510, 512 according to some examples. In one arrangement, first and second dies 504, 508 and SAX chip 506 may be disposed on one or more lead frames housed in a multichip module (MCM) package, e.g., encased in a molded encapsulant or a ceramic material operable to provide a hermetically sealed housing 502. In one arrangement, first and second dies 504, 508 may each include communication circuitry similar to the circuits 401A, 401B set forth above. In one arrangement, first die 504 and SAX chip 506 may be disposed on one lead frame 513 and second die 508 may be disposed on another lead frame 515, where inter-die communication may be effectuated through die-to-die wire bonds 505 and 507. With respect to external connectivity, wire bonds 511 may be provided between first die 504 and a first set of pins 517 and wire bonds 509 may be provided between second die 508 and a second set of pins 519. Depending on the application environment of the packaged device 500, the first set of pins 517 and the second set of pins 519 may be disposed in different voltage domains, e.g., having a high voltage separation (e.g., on the order of hundreds or thousands of volts).

Although FIG. 5 illustrates an MCM package containing laterally or horizontally spaced first and second dies 504, 508 and SAX chip 506, a stacked chip stack module or package may be provided in additional and/or alternative arrangements where first and second dies 504, 508 and SAX chip 506 may be vertically stacked. Furthermore, whereas SAX chip 506 may comprise nCT isolation transformers, some additional and/or alternative arrangements may include a SAX chip with CT isolation transformers where AEP circuit portions 510, 512 may provide additional protection against IEC currents although the risk of damage to the circuitry of first and second dies 504, 508 and/or the SAX dielectric material may be minimal.

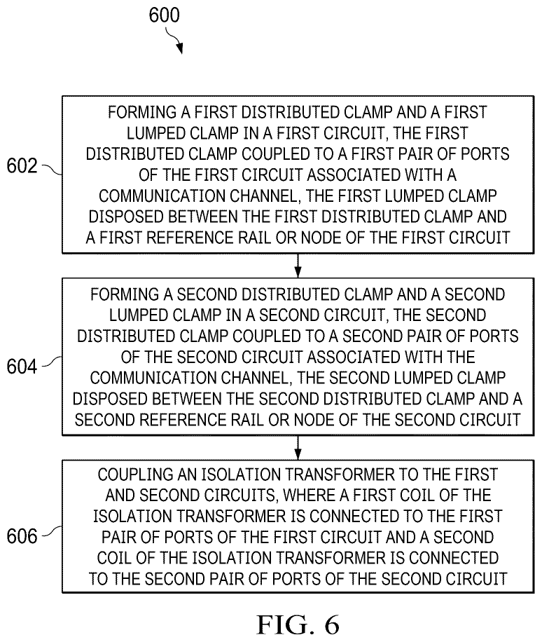

FIG. 6 is a flowchart of a method of fabrication of a microelectronic device according to some examples. An example method 600 may commence with forming a first distributed clamp and a first lumped clamp in a first circuit as set forth at block 602. The first distributed clamp may be coupled to a first pair of ports of the first circuit associated with a communication channel and the first lumped clamp may be disposed between the first distributed clamp and a first reference node of the first circuit. As set forth previously, the first distributed clamp and the first lumped clamp may be formed as GGNMOS devices in respective isolation tanks formed in a semiconductor substrate. At block 604, a second distributed clamp and a second lumped clamp may be formed in a second circuit. The second distributed clamp may be coupled to a second pair of ports of the second circuit associated with the communication channel and the second lumped clamp may be disposed between the second distributed clamp and a second reference node of the second circuit. Similar to the first distributed clamp and first lumped clamp, the second distributed clamp and the second lumped clamp may be formed as GGNMOS devices in respective isolation tanks formed in a semiconductor substrate. At block 606, an isolation transformer may be coupled to the first and second circuits, where a first coil of the isolation transformer is connected to the first pair of ports of the first circuit and a second coil of the isolation transformer is connected to the second pair of ports of the second circuit. As set forth previously, the isolation transformer may be integrated with the first and/or second circuits, e.g., in monolithic integration, according to some arrangements.

For purposes of the present disclosure, coils of an isolation transformer such as, e.g., transformers 104, 156, 250 and/or 450, may be provided as planar conductive windings horizontally disposed on two different metal levels formed over a substrate, where the metal levels may be separated by one or more dielectric material layers having a suitable total thickness. In some arrangements, the dielectric materials may include a combination of high-density plasma (HDP) oxide, nitride, oxynitride and/or PECVD tetraethyl orthosilicate (TEOS), etc., with a total thickness ranging from about 10 μm to about 25 μm or more.

In some examples where the isolation transformer is monolithically integrated into a circuit, the metal levels may be provided as part of a multilevel metal interconnect (MMI) fabricated in a back-end-of-line (BEOL) flow of the circuit. In some examples where the isolation transformer is provided as a standalone component (e.g., as a SAX component), the metal levels may not necessarily form an MMI arrangement of an IC. Further, an isolation transformer may be provided as a center tap transformer in some arrangements where one or both coils of the transformer may be provided with a separate contact within the coil winding (e.g., at a midpoint in the winding) in addition to contacts provided at respective coil terminals. In some arrangements, an isolation transformer may be provided as a non-center-tap transformer where there may be no contacts to the windings other than contacts at the coil terminals.

In some arrangements, a transformer coil may comprise one or more sections or portions of windings (which may also be referred to as “turns” or “loops”) separated by substantially rectilinear portions or sections (e.g., portions or sections with less curvature) that allow transitioning from one winding portion to an adjacent winding portion in a geometrical layout or configuration of the transformer. In some arrangements, a rectilinear/transitional section disposed between two winding portions of a coil may be provided with a contact operable as a center tap contact. In some arrangements, the rectilinear/transitional section disposed between two winding portions may be devoid of a center tap contact, e.g., as an nCT transformer implementation. In some arrangements, each winding portion of a transformer coil may contain a specific number of turns depending on application (e.g., tens or hundreds of turns). For example, more turns may be provided in corresponding winding portions of the coils where greater coupling between the coils is desired. In some arrangements, the turns of a winding portion of a transformer coil may have a circular shape in a top plan view, although other shapes may be implemented in additional and/or alternative arrangements. For example, winding portions having shapes such as obround, oval, diamond, racetrack, polygonal, triangular, rectangular, square, etc., may be provided in some isolation transformers including nCT transformers.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise. With respect to terms indicating a relative degree of variation in a value of a parameter or variable, such as, “around”, “about”, “approximately”, etc., such terms may indicate a percentage or fraction of variation in the value of the parameter or variable, e.g., ±5%, ±10%, etc., depending on the context unless otherwise specified.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. An isolator, comprising:
a first circuit including a first pair of ports;
a second circuit including a second pair of ports, the first and second pairs of ports configured to support a communication channel between the first and second circuits;
an isolation transformer disposed between the first and second circuits, wherein a first coil of the isolation transformer is coupled to the first pair of ports and a second coil of the isolation transformer is coupled to the second pair of ports;
a first distributed clamp coupled to the first pair of ports;
a first lumped clamp disposed between the first distributed clamp and a first reference node of the first circuit;
a second distributed clamp coupled to the second pair of ports; and
a second lumped clamp disposed between the second distributed clamp and a second reference node of the second circuit.

2. The isolator of claim 1, wherein the isolation transformer is a non-center-tap standalone transformer.

3. The isolator of claim 1, wherein the first distributed clamp and the second distributed clamp each comprise a pair of grounded-gate n-channel MOS (GGNMOS) transistors, each GGNMOS transistor of a respective pair having a corresponding source coupled to a shared node and each GGNMOS transistor of the respective pair having a corresponding drain coupled to a port of a corresponding pair of ports associated with the communication channel.

4. The isolator of claim 3, wherein the first lumped clamp comprises a GGNMOS transistor having a source coupled to the shared node of the first distributed clamp.

5. The isolator of claim 4, wherein a drain of the GGNMOS transistor of the first lumped clamp is coupled to the first reference node.

6. The isolator of claim 4, wherein the GGNMOS transistor of the first lumped clamp is at least ten times larger than the GGNMOS transistors of the first distributed clamp.

7. The isolator of claim 3, wherein the second lumped clamp comprises a GGNMOS transistor having a source coupled to the shared node of the second distributed clamp.

8. The isolator of claim 7, wherein a drain of the GGNMOS transistor of the second lumped clamp is coupled to the second reference node.

9. The isolator of claim 7, wherein the GGNMOS transistor of the second lumped clamp is at least ten times larger than the GGNMOS transistors of the second distributed clamp.

10. A semiconductor device, comprising:
a first MOS transistor formed over a semiconductor substrate and having a first gate, first source region and a first drain region;
a well extending into the semiconductor substrate;
second and third MOS transistors formed in or over the well, the second MOS transistor having a second gate, a second source region and a second drain region, and the third MOS transistor having a third gate, a third source region and a third drain region; and
a shared node that connects the well, the first gate, first source region, second source region, second gate, third source region and third gate.

11. The semiconductor device of claim 10, wherein the well is a first well and further comprising a second well, wherein the first MOS transistor is formed over the second well and the second and third MOS transistors are formed over the first well.

12. The semiconductor device of claim 10, further comprising a fourth MOS transistor having a fourth source region, fourth drain region and fourth gate, and a fifth MOS transistor having a fifth source region, fifth drain region and fifth gate, wherein the shared node is connected to the fourth and fifth source regions and fourth and fifth gates.

13. The semiconductor device of claim 12, wherein the second and third drain regions are connected to terminals of a first isolation transformer, and the fourth and fifth drain regions are connected to terminals of a second isolation transformer.

14. The semiconductor device of claim 10, wherein the MOS transistors are NMOS transistors.

15. The semiconductor device of claim 10, wherein the first drain region is connected to a power reference node.

16. The semiconductor device of claim 10, wherein the well has a first conductivity type and is formed within an isolation tank having an opposite second conductivity type, and the isolation tank is conductively connected to a positive voltage rail.

17. The semiconductor device of claim 10, wherein the first MOS transistor has a greater drive current capacity than the second and third MOS transistors.

18. The semiconductor device of claim 10, wherein the first MOS transistor has a first channel width at least ten times greater than a second channel width of the second and third MOS transistors.

19. A method, comprising:
forming a first distributed clamp and a first lumped clamp in a first circuit, the first distributed clamp coupled to a first pair of ports of the first circuit associated with a communication channel, the first lumped clamp disposed between the first distributed clamp and a first reference node of the first circuit;
forming a second distributed clamp and a second lumped clamp in a second circuit, the second distributed clamp coupled to a second pair of ports of the second circuit associated with the communication channel, the second lumped clamp disposed between the second distributed clamp and a second reference node of the second circuit; and
coupling an isolation transformer to the first and second circuits, wherein a first coil of the isolation transformer is connected to the first pair of ports of the first circuit and a second coil of the isolation transformer is connected to the second pair of ports of the second circuit.

20. The method of claim 19, wherein the isolation transformer is a non-center-tap standalone transformer.

21. The method of claim 19, wherein the first and second coils of the isolation transformer are formed as conductive windings disposed on different metal levels separated by a dielectric material.

22. A system, comprising:
a processing unit;
a signal isolator coupled to the processing unit; and
an interface coupled to the signal isolator, the signal isolator including an isolation barrier between a first circuit and a second circuit, wherein the first circuit is operable to communicate with the processing unit and the second circuit is operable to communicate with the interface, the first and second circuits each including a hierarchical electrostatic discharge (ESD) protection circuit operable to route ESD current that crosses the isolation barrier to a respective reference node of the first or second circuits.

23. The system of claim 22, wherein the isolation barrier comprises a plurality of non-center-tap standalone transformers (nCT SAX), each nCT SAX operable to provide isolation with respect to a corresponding communication channel between the first and second circuits.

24. The system of claim 22, wherein the interface is a computer peripheral interface and the system is a data center platform.

25. The system of claim 22, wherein the system is an electric vehicle.

26. The system of claim 22, wherein the hierarchical ESD protection circuit comprises:
a plurality of distributed clamps, each distributed clamp coupled between ports of a pair of ports configured to support a corresponding communication channel of a plurality of communication channels between the first and second circuits; and
a lumped clamp coupled to the plurality of distributed clamps, the lumped clamp configured to collect respective portions of the ESD current received via the plurality of distributed clamps and route the ESD current to the respective reference node.

27. An electronic circuit, comprising:
a first circuit portion configured to energize first and second interface nodes in a differential mode with a data signal; and
a second circuit portion configured to energize the first and second interface nodes in a common mode in response to an electrostatic discharge.

28. The electronic circuit of claim 27, wherein the second circuit portion comprises:
a distributed clamp coupled to the first and second interface nodes, the distributed clamp including a pair of grounded-gate n-channel MOS (GGNMOS) transistors having respective sources coupled to a shared node and each GGNMOS transistor having a corresponding drain coupled to a respective one of the first and second interface nodes; and
a lumped clamp including a GGNMOS transistor with a source coupled to the shared node and a drain coupled to a reference node of the electronic circuit.

29. The electronic circuit of claim 28, wherein the distributed clamp and the lumped clamp are each disposed in a respective isolation tank.

30. The electronic circuit of claim 29, wherein the isolation tank of the distributed clamp is coupled to a voltage rail via a pullup resistor.
